(19) United States
(12) Patent Application Publication
(10) Pub. No.: US 2026/0201248 A1
(43) Pub. Date: Jul. 16, 2026

(54) ETCHING SOLUTION COMPOSITION

(71) Applicant: RASA INDUSTRIES, LTD., Tokyo (JP)

(72) Inventors: Sho NAGAO, Tokyo (JP); Takao MITSUI, Tokyo (JP)

(21) Appl. No.: 19/135,439

(22) PCT Filed: Aug. 3, 2023
(86) PCT No.: PCT/JP2023/028410

§ 371 Date: Jun. 4, 2025

(30) Foreign Application Priority Data
Dec. 8, 2022 (JP) 2022-196435

(51) Int. Cl. C09K 13/06; H10P 50/68

(52) U.S. Cl. CPC C09K 13/06; H10P 50/683

(57) ABSTRACT

Provided is an etching solution composition capable of both having a higher etch selectivity of silicon nitride and reducing the deposition of silica on the surface of silicon oxide. An inorganic acid-based etching solution composition for selectively etching away silicon nitride from a semiconductor containing silicon nitride and silicon oxide, the etching solution composition comprising: an etch inhibitor that reduces etching of silicon oxide; and a deposition inhibitor that reduces deposition of silica on a surface of silicon oxide, wherein the etch inhibitor includes a first etch inhibitor having, in the molecular structure, at most three of alkoxy groups, hydroxy groups, and/or functional groups that are a precursor of a hydroxy group, and a second etch inhibitor having, in the molecular structure, at least four of alkoxy groups, hydroxy groups, and/or functional groups that are a precursor of a hydroxy group.

### TECHNICAL FIELD

The present invention relates to an inorganic acid-based etching solution composition for selectively etching away silicon nitride from a semiconductor containing silicon nitride and silicon oxide.

### BACKGROUND ART

The recent trend towards higher integration and capacity of semiconductor circuits has led to a demand for finer etching technology. For example, in fabrication of NAND flash memory having a three-dimensional structure (3D NAND), a silicon nitride film and a silicon oxide film are alternately layered, and the resultant structure is subjected to an etching process, i.e., is immersed in an etching solution. At that time, it is necessary to precisely remove only the silicon nitride film. To this end, a variety of etching solutions (compositions) have been developed so far in order to achieve a high etch selectivity in the etching process.

For example, Patent Document 1 describes an etching solution composition that is used in a fabrication process of a three-dimensional semiconductor, and that is a mixture of a solution containing silica and an alkali, phosphoric acid, and water. Patent Document 1 indicates that by using such an etching solution composition, the etching of the silicon oxide film is reduced, so that the etch selectivity of the silicon nitride film is improved (see paragraph [0013] in the description of Patent Document 1).

As another technique, Patent Document 2 describes an etching solution composition that is a mixture of water, phosphoric acid, and a hydroxyl group-containing solvent. Patent Document 2 indicates that examples of the hydroxyl group-containing solvent include polyols, glycols, and monovalent alcohols, and these components serve to protect the silicon oxide film, so that the silicon nitride film is etched with higher priority and selectively (see paragraph [0025] in the description of Patent Document 2).

### CITATION LIST

### Patent Literature

Patent Document 1: Japanese Unexamined Patent Application Publication No. 2020-96160
Patent Document 2: Japanese Unexamined Patent Application Publication No. 2018-207108

### SUMMARY OF INVENTION

### Technical Problem

Incidentally, when silicon nitride is etched using an etching solution composition containing phosphoric acid and water, ammonium phosphate [(NH₄)₃PO₄)] and silicic acid [SiOₓ(OH)₄₋₂ₓ]ₙ are generated in the solution. As the silicic acid concentration of the solution increases, silicic acid molecules undergo dehydration condensation to form silica [SiOₓ], which is likely to be deposited on the surface of silicon oxide. Such deposition may cause defects such as short circuits and defective interconnections in semiconductor products, and therefore, should be avoided to the extent possible.

In addition, in order to selectively etch away silicon nitride from a semiconductor containing silicon nitride and silicon oxide, it is necessary to increase the etch rate of silicon nitride and decrease the etch rate of silicon oxide. However, silicon oxide is also etched by water, and therefore, when an aqueous etching solution composition is used, it is necessary to take measures to reduce the etching of silicon oxide.

With regard to this, Patent Document 1 includes the wording “the etching of the silicon oxide film is reduced, so that the etch selectivity of the silicon nitride film is improved,” but indicates that the mechanism of exhibiting the effect has not been clarified (see paragraph [0013] in the description of Patent Document 1). In addition, the etching solution composition described in Patent Document 1 originally contains silicic acid, and therefore, it is considered that when silicon nitride is etched, the silicic acid concentration of the solution increases, so that silicic acid is more likely to be deposited in the form of silica on the surface of silicon oxide.

Patent Document 2 indicates that the etching solution composition protects the silicon oxide film with the hydroxyl group-containing solvent. However, the etch selectivity of silicon nitride of the etching solution composition itself is not sufficiently high. Data described in Patent Document 2 shows that the highest ratio (selectivity ratio) of the etch rates of silicon nitride and silicon oxide is as low as 137 (see FIGS. 2, 4, and 6 in Patent Document 2). In addition, although in Patent Document 2 it is recognized that water contained in the etching solution composition serves as a solvent, residue remover, viscosity modifier, and diluent (see paragraph [0021] in Patent Document 2), the effect of etching silicon oxide by water is not recognized or taken into account.

Thus, conventional etching solution compositions have difficulties in reducing the deposition of silica on the surface of silicon oxide while having a high selectivity ratio. There is still room for improvement in etching solution compositions.

With the above problems in mind, the present invention has been made. It is an object of the present invention to provide an etching solution composition that is capable of both having a high etch selectivity of silicon nitride and reducing the deposition of silica on the surface of silicon oxide.

### Solution to Problem

A characteristic feature of an etching solution composition according to the present invention for solving the above problem is an inorganic acid-based etching solution composition for selectively etching away silicon nitride from a semiconductor containing silicon nitride and silicon oxide, the etching solution composition comprising:
an etch inhibitor that reduces etching of silicon oxide; and
a deposition inhibitor that reduces deposition of silica on a surface of silicon oxide, wherein
the etch inhibitor includes a first etch inhibitor having, in the molecular structure, at most three of alkoxy groups, hydroxy groups, and/or functional groups that are a precursor of a hydroxy group, and a second etch inhibitor having, in the molecular structure, at least four of alkoxy groups, hydroxy groups, and/or functional groups that are a precursor of a hydroxy group.

With the etching solution composition thus configured, silicon nitride is mainly etched by the inorganic acid while the etch inhibitor reduces the etching of silicon oxide caused by water, resulting in an improvement in the etch selectivity of silicon nitride in the semiconductor containing silicon nitride and silicon oxide. Here, since the concentration of Si in the solution is low when silicon nitride has not been etched, the etch rate of silicon oxide is likely to be high. However, by using, as the etch inhibitor, a first etch inhibitor having, in the molecular structure, at most three of alkoxy groups, hydroxy groups, and/or functional groups that are a precursor of a hydroxy group, and a second etch inhibitor having, in the molecular structure, at least four of alkoxy groups, hydroxy groups, and/or functional groups that are a precursor of a hydroxy group, the etching of silicon oxide is persistently reduced, and therefore, the etch selectivity of silicon nitride can be maintained over a long period of time, without depending on the concentration of Si in the solution. In addition, the deposition inhibitor can reduce the deposition of silica on the surface of silicon oxide, resulting in prevention of the occurrence of defects such as short circuits and defective interconnections in semiconductor products.

In the etching solution composition of the present invention,
the first etch inhibitor is preferably a silane compound having an amino group.

The etching solution composition thus configured contains a silane compound having an amino group selected as the first etch inhibitor, and therefore, can have both the effect of reducing the etching of silicon oxide by the etch inhibitor and the effect of reducing the deposition of silica on the surface of silicon oxide by the deposition inhibitor, resulting in an improvement in the etch selectivity of silicon nitride.

In the etching solution composition of the present invention,
the first etch inhibitor preferably contains at least one selected from the group consisting of 3-aminopropyltrimethoxysilane, 3-aminopropyltriethoxysilane, N-2-(aminoethyl)-3-aminopropyltrimethoxysilane, and N-2-(aminoethyl)-3-aminopropylmethyldimethoxysilane, and hydrolysates of the alkoxysilanes.

The etching solution composition thus configured contains a preferable compound as the first etch inhibitor, and therefore, can have both the effect of reducing the etching of silicon oxide by the etch inhibitor and the effect of reducing the deposition of silica on the surface of silicon oxide by the deposition inhibitor, resulting in an improvement in the etch selectivity of silicon nitride.

In the etching solution composition of the present invention,
the second etch inhibitor is preferably a silane compound having at least one functional group selected from the group consisting of an alkyl group, an amino group, and a halogen group.

The etching solution composition thus configured contains a silane compound having at least one functional group selected from the group consisting of an alkyl group, an amino group, and a halogen group, which is selected as the second etch inhibitor, and therefore, can have both the effect of reducing the etching of silicon oxide by the etch inhibitor and the effect of reducing the deposition of silica on the surface of silicon oxide by the deposition inhibitor, resulting in an improvement in the etch selectivity of silicon nitride.

In the etching solution composition of the present invention,
the second etch inhibitor preferably contains at least one selected from the group consisting of 1,3-dimethyltetramethoxydisiloxane, represented by chemical structural formula (1):

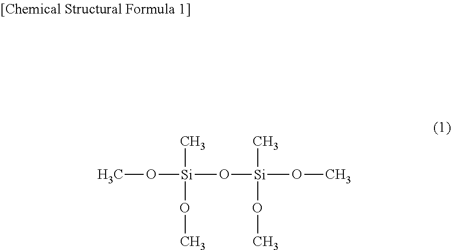

a siloxane compound represented by chemical structural formula (2):

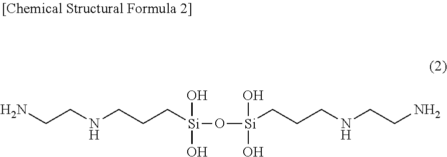 [SMILES: NCCNCCC[Si](O)(O)O[Si](O)(O)CCCNCCN]

a siloxane compound represented by chemical structural formula (3):

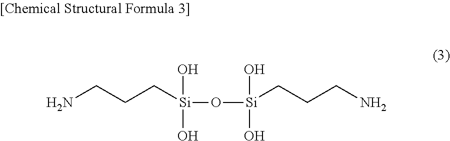 [SMILES: NCCC[Si](O)(O)O[Si](O)(O)CCCN]

hexamethoxydisiloxane, represented by chemical structural formula (4):

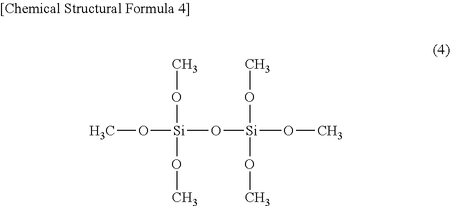

tetramethoxysilane, tetraethoxysilane, tetrabutoxysilane, tetrachloride silicon, and hexachlorodisilane.

The etching solution composition thus configured contains a preferable compound as the second etch inhibitor, and therefore, can have both the effect of reducing the etching of silicon oxide by the etch inhibitor and the effect of reducing the deposition of silica on the surface of silicon oxide by the deposition inhibitor, resulting in an improvement in the etch selectivity of silicon nitride.

In the etching solution composition of the present invention,
the deposition inhibitor preferably contains a hydrazide.

The etching solution composition thus configured contains a hydrazide selected as the deposition inhibitor, and therefore, has an excellent effect of reducing the deposition of silica on the surface of silicon oxide.

In the etching solution composition of the present invention,
the hydrazide preferably includes at least one selected from the group consisting of adipic acid dihydrazide, succinic acid dihydrazide, acetohydrazide chloride, succinic acid 2,2-dimethylhydrazide, and azelaic acid dihydrazide.

The etching solution composition thus configured contains a preferable compound as the deposition inhibitor, and therefore, has a more excellent effect of reducing the deposition of silica on the surface of silicon oxide.

In the etching solution composition of the present invention,
the etching solution composition is preferably free from Si derived from silicon nitride in the solution when the etching solution composition is unused.

The etching solution composition thus configured is free from Si derived from silicon nitride in the solution when the etching solution composition is unused. By using the brand-new etching solution composition, the etch selectivity of silicon nitride can be maintained over a long period of time.

In the etching solution composition of the present invention,
the etching solution composition is preferably allowed to be used repeatedly until the concentration of Si derived from silicon nitride in the solution reaches 3000 ppm.

The etching solution composition is allowed to be used repeatedly until the concentration of Si derived from silicon nitride in the solution reaches 3000 ppm. Therefore, the life of the solution is significantly extended compared to the life of conventional etching solutions (phosphoric acid), and the amount of the etching process is increased with a smaller amount of the solution, resulting in a significant cost reduction and excellent environmental friendliness. In addition, the etch inhibitor contained in the etching solution composition reduces the etching of the silicon oxide film, resulting in a higher etch selectivity of silicon nitride. Furthermore, a selectivity ratio [R₁/R₂] can be significantly improved while the deposition of silica on the surface of silicon oxide is reduced.

In the etching solution composition of the present invention,
a selectivity ratio [R₁/R₂] of a silicon nitride etch rate [R₁] to a silicon oxide etch rate [R₂] is preferably at least 5.3 times as high as that of an etching solution containing only the inorganic acid.

With the etching solution composition thus configured, the selectivity ratio [R₁/R₂] is at least 5.3 times as high as the selectivity ratio of an etching solution containing only the inorganic acid. Therefore, the etching solution composition is capable of both having a high etch selectivity of silicon nitride and reducing the deposition of silica on the surface of silicon oxide, and can also allow a quicker etching process.

### DESCRIPTION OF EMBODIMENTS

Embodiments of an etching solution composition according to the present invention will be described. It should be noted that the present invention is in no way intended to be limited to the embodiments described below.

### [Etching Solution Composition]

The etching solution composition of the present invention is used to selectively etch away silicon nitride from a semiconductor containing silicon nitride and silicon oxide. Components contained in the etching solution composition will be described below.

### <Inorganic Acid>

The etching solution composition of the present invention is based on an inorganic acid. Examples of the inorganic acid include phosphoric acid, sulfuric acid, nitric acid, hydrochloric acid, and mixtures of these inorganic acids. Of these inorganic acids, phosphoric acid is preferable. Phosphoric acid is used in the form of an aqueous solution when diluted in use, and the concentration thereof is preferably 50 to 100% by weight (wt %), more preferably 70 to 95 wt %, and even more preferably 85 to 95 wt %. It should be noted that the etching solution composition may be used with the phosphoric acid thereof adjusted to the above concentration. For example, the above appropriate concentration can be obtained by concentrating a stock solution containing a low-concentration aqueous phosphoric acid solution during or before use, by diluting a stock solution having a phosphoric acid concentration of more than 100 wt % (polyphosphoric acid) with water during or before use, or by dissolving phosphoric anhydride (P₂O₅) in water during or before use.

### <Etch Inhibitor>

The etching solution composition of the present invention contains an etch inhibitor that reduces the etching of silicon oxide. The etch inhibitor includes a plurality of etch inhibitors having different chemical structures. In this embodiment, for example, the etch inhibitor includes a first etch inhibitor and a second etch inhibitor. The first etch inhibitor is a compound having, in the molecular structure, at most three of alkoxy groups, hydroxy groups, and/or functional groups that are a precursor of a hydroxy group, preferably a silane compound having an amino group. The second etch inhibitor is a compound having, in the molecular structure, at least four of alkoxy groups, hydroxy groups, and/or functional groups that are a precursor of a hydroxy group, preferably a silane compound having at least one functional group selected from the group consisting of an alkyl group, an amino group, and a halogen group. The compound having a hydroxy group may be a compound that does not originally have a hydroxy group, and has a hydroxy group when the compound is in the solution.

### [First Etch Inhibitor]

Examples of the first etch inhibitor include methyltrimethoxysilane, dimethyldimethoxysilane, phenyltrimethoxysilane, dimethoxydiphenylsilane, methyltriethoxysilane, dimethyldiethoxysilane, phenyltriethoxysilane, n-propyltrimethoxysilane, n-propyltriethoxysilane, hexyltrimethoxysilane, hexyltriethoxysilane, octyltriethoxysilane, 1,6-bis(trimethoxysilyl)hexane, vinyltrimethoxysilane, 3-glycidoxypropylmethyldimethoxysilane, 3-glycidoxypropyltrimethoxysilane, p-styryltrimethoxysilane, 3-methacryloxypropyltrimethoxysilane, 3-acryloxypropyltrimethoxysilane, N-2-(aminoethyl)-3-aminopropyltrimethoxysilane, N-2-(aminoethyl)-4-aminobutyltrimethoxysilane, N-2-(aminoethyl)-5-aminopentyltrimethoxysilane, N-2-(aminoethyl)-6-aminohexyltrimethoxysilane, N-2-(aminoethyl)-3-aminopropylmethyldimethoxysilane, 3-aminopropyltrimethoxysilane, 3-aminopropyltriethoxysilane, 3-triethoxysilyl-N-(1,3-dimethyl-butylidene)propylamine, N-phenyl-3-aminopropyltrimethoxysilane, N-(vinylbenzyl)-2-aminoethyl-3-aminopropyltrimethoxysilane, a hydrochloride of each of the above aminosilanes, tris-(trimethoxysilylpropyl)isocyanurate, 3-mercaptopropylmethyldimethoxysilane, 3-isocyanatepropyltriethoxysilane, 3-trimethoxysilylpropylsuccinic anhydride, and a hydrolysate of each of the above alkoxysilanes. Of these first etch inhibitors, 3-aminopropyltrimethoxysilane, 3-aminopropyltriethoxysilane, N-2-(aminoethyl)-3-aminopropyltrimethoxysilane, N-2-(aminoethyl)-3-aminopropylmethyldimethoxysilane, and hydrolysates of these alkoxy silanes are preferable. These first etch inhibitors may be used alone or in a mixture of two or more thereof.

### [Second Etch Inhibitor]

The second etch inhibitor typically has a chemical structure represented by the following formula (I).

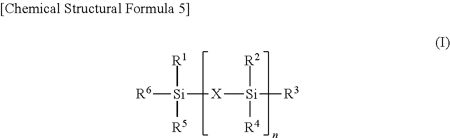

In formula (I), R₁ to R₆ represent a substituent. At least four of these substituents are at least one specific substituent selected from the group consisting of an alkoxy group, a hydroxy group, and chlorine. The substituents other than the specific substituent(s) are at least one substituent selected from the group consisting of an alkyl group, an aryl group, a carbonyl group, a carboxyl group, an amino group, an ethylene diamine group, and derivatives or complexes of these substituents. In formula (I), X represents “O” (oxygen atom) or “—” (single bond). In formula (I), n represents an integer of 0 to 3. Thus, the second etch inhibitor may be not only a compound having an alkoxy group (a siloxane compound or a disilane compound, the same applies to the following) or a compound having a hydroxy group, but also a compound having chlorine. It should be noted that the compound having an alkoxy group and the compound having chlorine are a compound that does not originally have a hydroxy group, and has a hydroxy group when the compound is hydrolyzed.

Specific examples of the second etch inhibitor include 1,3-dimethyltetramethoxydisiloxane, represented by the following chemical structural formula (1):

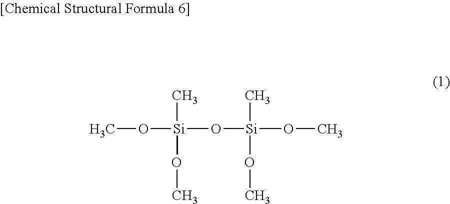

a siloxane compound represented by the following chemical structural formula (2):

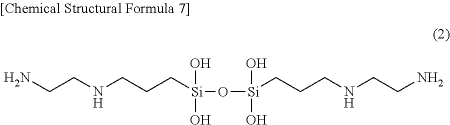 [SMILES: NCCNCCC[Si](O)(O)O[Si](O)(O)CCCNCCN]

a siloxane compound represented by the following chemical structural formula (3)

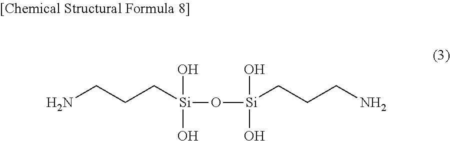 [SMILES: NCCC[Si](O)(O)O[Si](O)(O)CCCN]

hexamethoxydisiloxane, represented by the following chemical structural formula (4):

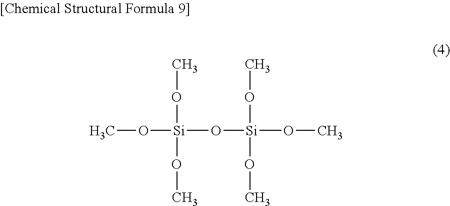

tetramethoxysilane, tetraethoxysilane, tetrabutoxysilane, hexamethoxydisilane, hexaethoxydisilane, hexabutoxydisilane, hexamethoxydisiloxane, hexaethoxydisiloxane, hexabutoxydisiloxane, 1,3-dimethyltetraethoxydisiloxane, 1,3-dimethyltetrabutoxydisiloxane, 1,3-diethyltetramethoxydisiloxane, 1,3-diethyltetraethoxydisiloxane, 1,3-diethyltetrabutoxydisiloxane, 1,3-divinyltetramethoxydisiloxane, 1,3-divinyltetraethoxydisiloxane, 1,3-divinyltetrabutoxydisiloxane, 1,3-bis(3-aminopropyl)tetramethoxydisiloxane, tetrachloride silicon, hexachlorodisilane, hexachlorodisiloxane, 1,3-dimethyltetrachlorodisiloxane, 1,3-diethyltetrachlorodisiloxane, and 1,3-dibutyltetrachlorodisiloxane. Incidentally, examples of the siloxane compound that is commercially available include the silane coupling agents “X-12-1098,” “X-12-1135,” “KBP-64,” and “KBP-90,” manufactured by Shin-Etsu Chemical Co., Ltd. The above second etch inhibitors may be used alone or in a mixture of two or more thereof.

### [Contained Amount of Etch Inhibitor]

Concerning the amount of the etch inhibitor contained in the etching solution composition, the contained amount of the first etch inhibitor is preferably 0.5 to 20 wt %, more preferably 1 to 20 wt %, and even more preferably 1 to 6 wt %. The contained amount of the second etch inhibitor is preferably 0.01 to 5 wt %, more preferably 0.01 to 1 wt %, and even more preferably 0.09 to 0.6 wt %.

### <Deposition Inhibitor>

The etching solution composition of the present invention contains a deposition inhibitor that reduces the deposition of silica on the surface of silicon oxide. Examples of the deposition inhibitor include hydrazine compounds, pyrazoles, triazoles, hydrazides, compounds having an imidazole backbone, compounds having a pyrrolidine backbone, compounds having a piperidine backbone, compounds having a morpholine backbone, compounds having a pyridine backbone, phosphonic acid compounds, compounds having a quaternary ammonium backbone, compounds having a pyrimidine backbone, compounds having a purine backbone, and compounds having a urea backbone. Hydrazides are preferably used. The above compounds and substances may be used alone or in a mixture of two or more thereof. When at least two different deposition inhibitors are used, the etching solution composition is considerably useful in terms of not only performance in the etching process but also the longer life and cost reduction of the solution. The amount of the deposition inhibitor contained in the etching solution composition is preferably 0.1 to 1 wt %, more preferably 0.3 to 0.4 wt %.

### [Hydrazine Compounds]

Examples of the hydrazine compounds include hydrazine, butylhydrazine, isopropylhydrazine, benzylhydrazine, N,N-dimethylhydrazine, 1,2-diacetylhydrazine, phenylhydrazine, N,N-dicarbamoylhydrazine, hydrazine sulfate, hydrazine monohydrochloride, hydrazine dihydrochloride, butylhydrazine hydrochloride, hydrazine carbonate, and hydrazine monohydrobromide. These hydrazine compounds may be used alone or in a mixture of two or more thereof.

### [Pyrazoles]

Examples of the pyrazoles include 3,5-dimethylpyrazole and 3-methyl-5pyrazon. These pyrazoles may be used alone or in a mixture of two or more thereof.

### [Triazoles]

Examples of the triazoles include 4-amino-1,2,4-triazole, 1,2,4-triazole, 1,2,3-triazole, 1-hydroxybenzotriazole, and 3-mercapto-1,2,4-triazole. These triazoles may be used alone or in a mixture of two or more thereof.

### [Hydrazides]

Examples of the hydrazides include propionic acid hydrazide, laurylic acid hydrazide, salicylic acid hydrazide, formohydrazide, acetohydrazide, acetohydrazide chloride, p-hydroxybenzoic acid hydrazide, naphthoic acid hydrazide, 3-hydroxy-2-naphthoic acid hydrazide, benzhydrazide, carbodihydrazide, oxalic acid dihydrazide, malonic acid dihydrazide, succinic acid dihydrazide, succinic acid 2,2-dimethylhydrazide, glutaric acid dihydrazide, adipic acid dihydrazide, azelaic acid dihydrazide, sebacic acid dihydrazide, dodecanedioic acid dihydrazide, maleic acid dihydrazide, fumaric acid dihydrazide, tartaric acid dihydrazide, malic acid dihydrazide, diglycolic acid dihydrazide, isophthalic acid dihydrazide, terephthalic acid dihydrazide, 2,6-naphthalenedicarboxylic acid dihydrazide, 2,6-naphthoic acid dihydrazide, citric acid trihydrazide, pyromellitic acid trihydrazide, 1,2,4-benzenetricarboxylic acid trihydrazide, nitrilotriacetic acid trihydrazide, 1,3,5-cyclohexanetricarboxylic acid trihydrazide, ethylenediaminetetraacetic acid tetrahydrazide, and 1,4,5,8-naphthoic acid tetrahydrazide. Of these hydrazides, adipic acid dihydrazide, succinic acid dihydrazide, acetohydrazide chloride, succinic acid 2,2-dimethylhydrazide, and azelaic acid dihydrazide are preferable. These hydrazides may be used alone or in a mixture of two or more thereof.

### [Compounds Having Imidazole Backbone]

Examples of the compounds having an imidazole backbone include compounds such as imidazole, imidazolecarboxylic acid, imidurea, diazolidinyl urea, 3-(2-oxoimidazolidin-1-yl)benzate, and imidazolehydrochlorides, and imidazolium salts such as 1-ethyl-3-methylimidazolium chloride, 1-butyl-3-methylimidazolium chloride, 1,3-dimethylimidazoliummethyl sulfate, 1-ethyl-3-methylimidazolium acetate, 1-ethyl-3-octylimidazolium tetrafluoroborate, 1,3-dimethylimidazolium dimethylphosphate, 1-ethyl-3-methylimidazolium tetrafluoroborate, and 1-ethyl-3-methylimidazolium hexafluorophosphate. These compounds having an imidazole backbone may be used alone or in a mixture of two or more thereof.

### [Compounds Having Pyrrolidine Backbone]

Examples of the compounds having a pyrrolidine backbone include compounds such as pyrrolidine, 2-pyrrolidone, N-methylpyrrolidone, N-vinyl-2-pyrrolidone, pyroglutamic acid, and piracetam, and pyrrolidinium salts such as 1-ethyl-1-methylpyrrolidinium chloride, 1-butyl-1-methylpyrrolidinium chloride, 1-ethyl-1-methylpyrrolidinium acetate, 1-ethyl-1-methylpyrrolidinium tetrafluoroborate, 1-butyl-1-methylpyrrolidinium tetrafluoroborate, 1-ethyl-1-methylpyrrolidinium hexafluorophosphate, and 1-butyl-1-methylpyrrolidinium hexafluorophosphate. These compounds having a pyrrolidine backbone may be used alone or in a mixture of two or more thereof.

### [Compounds Having Piperidine Backbone]

Examples of the compounds having a piperidine backbone include compounds such as piperidine, ethylpiperidine-4-carboxylate, piperidin-2-ylacetate, and methylpiperidine-4-carboxamide, and piperidinium salts such as (piperidinium-1-ylmethyl)trifluoroborate, 1-butyl-1-methylpiperidinium bromide, and 1-butyl-1-methylpiperidinium bisimide. These compounds having a piperidine backbone may be used alone or in a mixture of two or more thereof.

### [Compounds Having Morpholine Backbone]

Examples of the compounds having a morpholine backbone include compounds such as morpholine, morpholin-2-ylmethanol, morpholin-3-one, morpholine-4-carbothioic acid amide, morpholin-4-ylacetate, and morpholine-4-ylethylacetate, and morpholinium salts such as 4-ethyl-4-methylmorpholinium bromide, and 4-(2-ethoxyethyl)-4-methylmorpholinium bisimide. These compounds having a morpholine backbone may be used alone or in a mixture of two or more thereof.

### [Compounds Having Pyridine Backbone]

Examples of the compounds having a pyridine backbone include compounds such as pyridine, N,N-dimethyl-4-aminopyridine, bipyridine, 2,6-lutidine, and pyridinium p-toluenesulfonate, and pyridinium salts such as 1-butyl-3-methylpyridinium chloride, 1-butylpyridinium tetrafluoroborate, and 1-butyl-pyridinium hexafluorophosphate. These compounds having a pyridine backbone may be used alone or in a mixture of two or more thereof.

### [Phosphonic Acid Compounds]

Examples of the phosphonic acid compounds include compounds such as phosphonic acid, diphenyl phosphonate, butyl phosphonate, dipentyl phosphonate, and ammonium phosphate, and phosphonium salts such as tetrabutylphosphonium hexafluorophosphate, tetrabutylphosphonium bisimide, and tetrabutylphosphonium bromide. These phosphonic acid compounds may be used alone or in a mixture of two or more thereof.

### [Compounds Having Quaternary Ammonium Backbone]

Examples of the compounds having a quaternary ammonium backbone include tetramethylammonium chloride, tetrabutylammonium chloride, tetramethylammonium bromide, tetramethylammonium hydroxide, tetramethylammonium iodide, tetrabutylammonium bromide, tetrabutylammonium hydrogen sulfate, tetramethylammonium hexafluorophosphate, tetrabutylammonium hexafluorophosphate, and choline acetate. These compounds having a quaternary ammonium backbone may be used alone or in a mixture of two or more thereof.

### [Compounds Having Pyrimidine Backbone]

Examples of the compounds having a pyrimidine backbone include thymine, cytosine, uracil, and nucleosides, ribonucleosides, and deoxyribonucleosides thereof. These compounds having a pyrimidine backbone may be used alone or in a mixture of two or more thereof.

### [Compounds Having Purine Backbone]

Examples of the compounds having a purine backbone include purine, adenine, guanine, uric acid, caffeine, hypoxanthine, xanthine, theophylline, theobromine, isoguanine, and nucleosides, ribonucleotides, and deoxyribonucleotides thereof. These compounds having a purine backbone may be used alone or in a mixture of two or more thereof.

### [Compounds Having Urea Backbone]

Examples of the compounds having a urea backbone include urea, hydroxyurea, N,N-diethylthiourea, N,N-dibutylthiourea, biurea, biuret, and N-amidinothiourea. These compounds having a urea backbone may be used alone or in a mixture of two or more thereof.

### [Formulation of Etching Solution Composition]

The etching solution composition of the present invention is formulated by adding an etch inhibitor and a deposition inhibitor to an inorganic acid as the base thereof. Here, the etch inhibitor and the deposition inhibitor can be directly added to the inorganic acid. Alternatively, the etch inhibitor and the deposition inhibitor may be dissolved or suspended in a solvent, which is then added to the inorganic acid. The etch inhibitor and the deposition inhibitor may be added to the inorganic acid at room temperature or while the solution is being heated.

### <Solvent>

Examples of the solvent for dissolving or suspending the etch inhibitor and the deposition inhibitor include water, alcohols such as methanol, ethanol, 2-propanol, butanol, octanol, benzyl alcohol, ethylene glycol, propylene glycol, diethylene glycol, triethylene glycol, and 2,2,2-trifluoroethanol, ethers such as diethyl ether, diisopropyl ether, dibutyl ether, cyclopentylmethyl ether (CPME), tetrahydrofuran (THF), 2-methyltetrahydrofuran, 1,4-dioxane, and dimethoxy ethane, carbonic acid esters such as ethylene carbonate, propylene carbonate, dimethyl carbonate, diethyl carbonate, ethylmethyl carbonate, and 4-fluoroethylenecarbonate, esters such as methyl formate, ethyl formate, propyl formate, methyl acetate, ethyl acetate, butyl acetate, methyl propionate, ethyl propionate, methyl butyrate, and γ-lactone, nitriles such as acetonitrile, propionitrile, valeronitrile, glutaronitrile, adiponitrile, methoxyacetonitrile, 3-methoxypropionitrile, and benzonitrile, amides such as N,N-dimethylformamide (DMF), N,N-dimethylacetamide (DMAc), and N-methylpyrrolidone (NMP), ureas such as dimethyl sulfoxide (DMSO), hexamethylphosphoric triamide (HMPA), N,N,N′,N′-tetramethylurea (TMU), and N,N′-dimethylpropyleneurea (DMPU), and ionic liquids such as imidazolium salts, pyrrolidinium salts, piperidinium salts, pyridinium salts, morpholinium salts, phosphonium salts, quaternary ammonium salts, and sulfonium salts. Concerning the ionic liquids, examples of the cation include an imidazolium backbone, pyrrolidinium backbone, piperidinium backbone, morpholinium backbone, pyridinium backbone, quaternary phosphonium backbone, quaternary ammonium backbone, and sulfonium backbone, and examples of the anion include Br⁻, BF₄⁻, PF₆⁻, (CN)₂N⁻, Cl⁻, I⁻, (CF₃SO₂)N⁻, (F₂SO₂)N⁻, CH₃COO⁻, HSO₄⁻, (CH₃)₂PO₄⁻, CF₃COO⁻, CH₃SO₃⁻, CF₃SO₃⁻, and SCN⁻. These solvents may be used alone or in a mixture of two or more thereof.

### <Surfactant>

The etch inhibitor and the deposition inhibitor may be dissolved or suspended in the solvent in combination with a surfactant. As the surfactant, any of cationic surfactants, anionic surfactants, amphoteric surfactants, and nonionic surfactants may be used, or a combination of these surfactants may be used.

The etching solution composition of the present invention is significantly characterized in that the etching solution composition can be used when the concentration of Si derived from silicon nitride in the solution is in a predetermined concentration range or until the concentration of Si derived from silicon nitride in the solution is a predetermined concentration. For conventional etching solutions (phosphoric acid), as the period of time during which the etching solution is used or the number of times the etching solution is used increases, the concentration of Si derived from silicon nitride in the solution increases. When the Si concentration is at a certain high level, silica will be deposited. It is necessary to dispose of the solution as a less effective solution or recover and regenerate the less effective solution. In contrast, the etching solution composition of the present invention is capable of reducing the deposition of silica even when the concentration of Si derived from silicon nitride in the solution increases. As a result, the life of the solution is significantly extended compared to the life of conventional etching solutions (phosphoric acid), and the amount of the etching process is increased with a smaller amount of the solution, resulting in a significant cost reduction and excellent environmental friendliness. In addition, the etch inhibitor contained in the etching solution composition reduces the etching of the silicon oxide film, resulting in a higher etch selectivity of silicon nitride.

Here, the concentration (predetermined concentration) of Si derived from silicon nitride in the solution will be described. As described above, although the etching solution composition of the present invention can be used when the concentration of Si derived from silicon nitride in the solution is in a predetermined concentration range (i.e., the etching solution composition of the present invention can be used even when the Si concentration increased due to the etching of silicon nitride is significantly higher than in the conventional art), the component Si of the etching solution composition includes one that is derived from the silane coupling agent and the like. However, the silane coupling agent and the like maintain the stable structure in the etching solution even at any high temperature, and therefore, the component Si derived from the silane coupling agent and the like is not involved in the reduction in performance of the etching solution composition due to the deposition of silica, or the like. In addition, the component Si derived from the silicon nitride film exists in the form of silicic acid [SiOₓ(OH)₄₋₂ₓ]ₙ in the etching solution. In this case, the above predetermined concentration is at most 3000 ppm (e.g., any concentration of 0 to 3000 ppm), i.e., the etching solution composition can be used until the concentration of Si derived from silicon nitride in the solution reaches 3000 ppm. It should be noted that the unit (ppm) of the concentration of Si derived from silicon nitride in the etching solution is herein expressed as weight by weight (mg/kg).

The etching solution composition of the present invention thus formulated can have a high etch selectivity of silicon nitride, i.e., the ratio [R₁/R₂](selectivity ratio) of the etch rate [R₁] of silicon nitride to the etch rate [R₂] of silicon oxide can be at least 5.3 times as high as the selectivity ratio of an etching solution containing only an inorganic acid. An etching solution composition having such a high selectivity ratio [R₁/R₂] is capable of both having a high etch selectivity of silicon nitride and reducing the deposition of silica on the surface of silicon oxide, and can also allow a quicker etching process. It should be noted that the ratio of the selectivity ratio [R₁/R₂] of the etching solution composition of the present invention to the selectivity ratio of an etching solution containing only an inorganic acid is preferably at least 9, more preferably at least 18. When an etching process is performed using an etching solution composition having such a high selectivity ratio [R₁/R₂] compared to an etching solution containing only an inorganic acid, the occurrence of defects such as short circuits and defective interconnections in semiconductor products can be reduced, which is significantly beneficial to industrial production (process) of semiconductor products.

### EXAMPLES

Examples of the etching solution composition of the present invention will be described. In the examples, in order to investigate the performance of the etching solution composition, an etch test was conducted using a portion of the fabrication process of a 3D NAND.

### <Formulation of Etching Solution Compositions>

As a phosphoric acid-based etching solution composition according to the present invention, etching solution compositions according to Examples 1 to 34 each containing the first etch inhibitor and the second etch inhibitor as the etch inhibitor, and the deposition inhibitor, were formulated. In addition, for comparison, etching solution compositions according to Comparative Examples 1 to 6 and 14 to 16 each containing only the first etch inhibitor as the etch inhibitor, and the deposition inhibitor, etching solution compositions according to Comparative Examples 7 to 13 and 17 to 19 each containing only the second etch inhibitor as the etch inhibitor, and the deposition inhibitor, were formulated. Furthermore, for reference, an etching solution (phosphoric acid) according to Reference Example 1 containing neither an etch inhibitor nor a deposition inhibitor was formulated. Methods for formulating the etching solution compositions and etching solutions will be described below.

### Example 1

An aqueous phosphoric acid solution having a concentration of 85 wt % (manufactured by Rasa Industries, Ltd., hereinafter referred to as an “85% phosphoric acid” or the like) was used as an inorganic acid that serves as a base. The 85% phosphoric acid was concentrated into an 87% phosphoric acid. To the 87% phosphoric acid, 3.00 wt % of 3-aminopropyltrimethoxysilane (manufactured by Shin-Etsu Chemical Co., Ltd.) as the first etch inhibitor, 0.20 wt % of 1,3-dimethyltetramethoxydisiloxane (manufactured by Fluorochem Ltd.) having chemical structural formula (1) below as the second etch inhibitor, and 0.30 wt % of adipic acid dihydrazide (manufactured by Fujifilm Wako Pure Chemical Corporation) were added and dissolved to obtain an etching solution composition of Example 1.

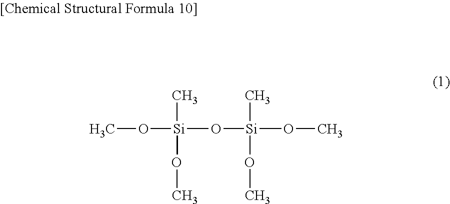

### Example 2

A predetermined amount of silicon nitride was dissolved in the etching solution composition of Example 1 so that the concentration of Si derived from silicon nitride in the solution was adjusted to 200 ppm, to obtain an etching solution composition of Example 2, which thus originally contained silicon nitride. It should be noted that the concentration of Si derived from silicon nitride in the solution was measured by a method described below in the “Method for Measuring Concentration of Si Derived from Silicon Nitride” section (the same applies to the following examples and comparative examples).

### Example 3

To an 87% phosphoric acid prepared by a procedure similar to that of Example 1, 3.00 wt % of 3-aminopropyltrimethoxysilane (manufactured by Shin-Etsu Chemical Co., Ltd.) as the first etch inhibitor, 0.09 wt % of a siloxane compound having chemical structural formula (2) below as the second etch inhibitor, and 0.30 wt % of adipic acid dihydrazide (manufactured by Fujifilm Wako Pure Chemical Corporation) as the deposition inhibitor, were added and dissolved to obtain an etching solution composition of Example 3.

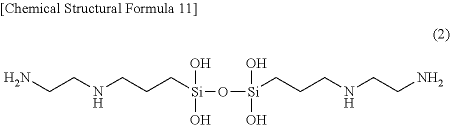 [SMILES: NCCNCCC[Si](O)(O)O[Si](O)(O)CCCNCCN]

### Example 4

A predetermined amount of silicon nitride was dissolved in the etching solution composition of Example 3 so that the concentration of Si derived from silicon nitride in the solution was adjusted to 200 ppm, to obtain an etching solution composition of Example 4, which thus originally contained silicon nitride.

### Example 5

To an 87% phosphoric acid prepared by a procedure similar to that of Example 1, 4.00 wt % of 3-aminopropyltrimethoxysilane (manufactured by Shin-Etsu Chemical Co., Ltd.) as the first etch inhibitor, 0.60 wt % of a siloxane compound having chemical structural formula (3) below as the second etch inhibitor, and 0.30 wt % of succinic acid dihydrazide (manufactured by Fujifilm Wako Pure Chemical Corporation) as the deposition inhibitor, were added and dissolved to obtain an etching solution composition of Example 5.

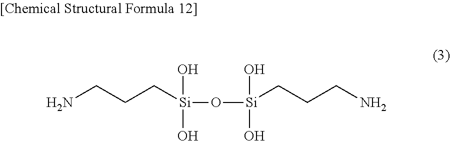 [SMILES: NCCC[Si](O)(O)O[Si](O)(O)CCCN]

### Example 6

A predetermined amount of silicon nitride was dissolved in the etching solution composition of Example 5 so that the concentration of Si derived from silicon nitride in the solution was adjusted to 200 ppm, to obtain an etching solution composition of Example 6, which thus originally contained silicon nitride.

### Example 7

To an 87% phosphoric acid prepared by a procedure similar to that of Example 1, 4.00 wt % of 3-aminopropyltriethoxysilane (manufactured by Shin-Etsu Chemical Co., Ltd.) as the first etch inhibitor, 0.20 wt % of 1,3-dimethyltetramethoxydisiloxane (manufactured by Fluorochem Ltd.), represented by chemical structural formula (1) below, as the second etch inhibitor, and 0.30 wt % of succinic acid dihydrazide (manufactured by Fujifilm Wako Pure Chemical Corporation) as the deposition inhibitor, were added and dissolved to obtain an etching solution composition of Example 7.

### Example 8

A predetermined amount of silicon nitride was dissolved in the etching solution composition of Example 7 so that the concentration of Si derived from silicon nitride in the solution was adjusted to 200 ppm, to obtain an etching solution composition of Example 8, which thus originally contained silicon nitride.

### Example 9

To an 87% phosphoric acid prepared by a procedure similar to that of Example 1, 4.00 wt % of 3-aminopropyltriethoxysilane (manufactured by Shin-Etsu Chemical Co., Ltd.) as the first etch inhibitor, 0.09 wt % of the siloxane compound represented by chemical structural formula (2) as the second etch inhibitor, and 0.30 wt % of acetohydrazide chloride (manufactured by Fujifilm Wako Pure Chemical Corporation) as the deposition inhibitor, were added and dissolved to obtain an etching solution composition of Example 9.

### Example 10

A predetermined amount of silicon nitride was dissolved in the etching solution composition of Example 9 so that the concentration of Si derived from silicon nitride in the solution was adjusted to 200 ppm, to obtain an etching solution composition of Example 10, which thus originally contained silicon nitride.

### Example 11

To an 87% phosphoric acid prepared by a procedure similar to that of Example 1, 4.00 wt % of 3-aminopropyltriethoxysilane (manufactured by Shin-Etsu Chemical Co., Ltd.) as the first etch inhibitor, 0.09 wt % of the siloxane compound represented by chemical structural formula (2) as the second etch inhibitor, and 0.30 wt % of succinic acid 2,2-dimethylhydrazide (manufactured by Fujifilm Wako Pure Chemical Corporation) as the deposition inhibitor, were added and dissolved to obtain an etching solution composition of Example 11.

### Example 12

A predetermined amount of silicon nitride was dissolved in the etching solution composition of Example 11 so that the concentration of Si derived from silicon nitride in the solution was adjusted to 200 ppm, to obtain an etching solution composition of Example 12, which thus originally contained silicon nitride.

### Example 13

To an 87% phosphoric acid prepared by a procedure similar to that of Example 1, 3.00 wt % of N-2-(aminoethyl)-3-aminopropyltrimethoxysilane (manufactured by Shin-Etsu Chemical Co., Ltd.) as the first etch inhibitor, 0.12 wt % of the siloxane compound represented by chemical structural formula (2) as the second etch inhibitor, and 0.30 wt % of adipic acid dihydrazide (manufactured by Fujifilm Wako Pure Chemical Corporation) as the deposition inhibitor, were added and dissolved to obtain an etching solution composition of Example 13.

### Example 14

A predetermined amount of silicon nitride was dissolved in the etching solution composition of Example 13 so that the concentration of Si derived from silicon nitride in the solution was adjusted to 200 ppm, to obtain an etching solution composition of Example 14, which thus originally contained silicon nitride.

### Example 15

To an 87% phosphoric acid prepared by a procedure similar to that of Example 1, 6.00 wt % of N-2-(aminoethyl)-3-aminopropylmethyldimethoxysilane (manufactured by Shin-Etsu Chemical Co., Ltd.) as the first etch inhibitor, 0.09 wt % of the siloxane compound represented by chemical structural formula (2) as the second etch inhibitor, and 0.30 wt % of acetohydrazide chloride (manufactured by Fujifilm Wako Pure Chemical Corporation) as the deposition inhibitor, were added and dissolved to obtain an etching solution composition of Example 15.

### Example 16

A predetermined amount of silicon nitride was dissolved in the etching solution composition of Example 15 so that the concentration of Si derived from silicon nitride in the solution was adjusted to 200 ppm, to obtain an etching solution composition of Example 16, which thus originally contained silicon nitride.

### Example 17

To an 87% phosphoric acid prepared by a procedure similar to that of Example 1, 4.00 wt % of 3-aminopropyltrimethoxysilane (manufactured by Shin-Etsu Chemical Co., Ltd.) as the first etch inhibitor, 0.04 wt % of tetramethoxysilane (manufactured by Fujifilm Wako Pure Chemical Corporation) as the second etch inhibitor, and 0.30 wt % of azelaic acid dihydrazide (manufactured by Fujifilm Wako Pure Chemical Corporation) as the deposition inhibitor, were added and dissolved to obtain an etching solution composition of Example 17.

### Example 18

A predetermined amount of silicon nitride was dissolved in the etching solution composition of Example 17 so that the concentration of Si derived from silicon nitride in the solution was adjusted to 200 ppm, to obtain an etching solution composition of Example 18, which thus originally contained silicon nitride.

### Example 19

To an 87% phosphoric acid prepared by a procedure similar to that of Example 1, 4.00 wt % of 3-aminopropyltriethoxysilane (manufactured by Shin-Etsu Chemical Co., Ltd.) as the first etch inhibitor, 0.20 wt % of tetraethoxy silane (manufactured by Fujifilm Wako Pure Chemical Corporation) as the second etch inhibitor, and 0.40 wt % of adipic acid dihydrazide (manufactured by Fujifilm Wako Pure Chemical Corporation) as the deposition inhibitor, were added and dissolved to obtain an etching solution composition of Example 19.

### Example 20

A predetermined amount of silicon nitride was dissolved in the etching solution composition of Example 19 so that the concentration of Si derived from silicon nitride in the solution was adjusted to 200 ppm, to obtain an etching solution composition of Example 20, which thus originally contained silicon nitride.

### Example 21

To an 87% phosphoric acid prepared by a procedure similar to that of Example 1, 4.00 wt % of N-2-(aminoethyl)-3-aminopropyltrimethoxysilane (manufactured by Shin-Etsu Chemical Co., Ltd.) as the first etch inhibitor, 0.30 wt % of tetrabutoxysilane (manufactured by Fujifilm Wako Pure Chemical Corporation) as the second etch inhibitor, and 0.40 wt % of adipic acid dihydrazide (manufactured by Fujifilm Wako Pure Chemical Corporation) as the deposition inhibitor, were added and dissolved to obtain an etching solution composition of Example 21.

### Example 22

A predetermined amount of silicon nitride was dissolved in the etching solution composition of Example 21 so that the concentration of Si derived from silicon nitride in the solution was adjusted to 200 ppm, to obtain an etching solution composition of Example 22, which thus originally contained silicon nitride.

### Example 23

To an 87% phosphoric acid prepared by a procedure similar to that of Example 1, 4.00 wt % of 3-aminopropyltrimethoxysilane (manufactured by Shin-Etsu Chemical Co., Ltd.) as the first etch inhibitor, 0.10 wt % of tetrachloride silicon (manufactured by Tokyo Chemical Industry Co., Ltd.) as the second etch inhibitor, and 0.30 wt % of adipic acid dihydrazide (manufactured by Fujifilm Wako Pure Chemical Corporation) as the deposition inhibitor, were added and dissolved to obtain an etching solution composition of Example 23.

### Example 24

A predetermined amount of silicon nitride was dissolved in the etching solution composition of Example 23 so that the concentration of Si derived from silicon nitride in the solution was adjusted to 200 ppm, to obtain an etching solution composition of Example 24, which thus originally contained silicon nitride.

### Example 25

To an 87% phosphoric acid prepared by a procedure similar to that of Example 1, 4.00 wt % of 3-aminopropyltriethoxysilane (manufactured by Shin-Etsu Chemical Co., Ltd.) as the first etch inhibitor, 0.05 wt % of hexachlorodisilane (manufactured by Tokyo Chemical Industry Co., Ltd.) as the second etch inhibitor, and 0.40 wt % of acetohydrazide chloride (manufactured by Fujifilm Wako Pure Chemical Corporation) as the deposition inhibitor, were added and dissolved to obtain an etching solution composition of Example 25.

### Example 26

A predetermined amount of silicon nitride was dissolved in the etching solution composition of Example 25 so that the concentration of Si derived from silicon nitride in the solution was adjusted to 200 ppm, to obtain an etching solution composition of Example 26, which thus originally contained silicon nitride.

### Example 27

To an 87% phosphoric acid prepared by a procedure similar to that of Example 1, 4.00 wt % of 3-aminopropyltrimethoxysilane (manufactured by Shin-Etsu Chemical Co., Ltd.) as the first etch inhibitor, 0.05 wt % of hexamethoxydisiloxane, having chemical structural formula (4) below, as the second etch inhibitor, and 0.40 wt % of adipic acid dihydrazide (manufactured by Fujifilm Wako Pure Chemical Corporation) as the deposition inhibitor, were added and dissolved to obtain an etching solution composition of Example 27.

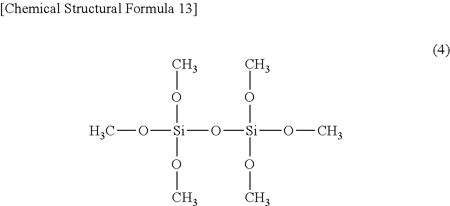

### Example 28

A predetermined amount of silicon nitride was dissolved in the etching solution composition of Example 27 so that the concentration of Si derived from silicon nitride in the solution was adjusted to 200 ppm, to obtain an etching solution composition of Example 28, which thus originally contained silicon nitride.

### Example 29

An 80% phosphoric acid was obtained by diluting an 85% phosphoric acid (manufactured by Rasa Industries, Ltd.). To the 80% phosphoric acid, 15.70 wt % of 3-aminopropyltrimethoxysilane (manufactured by Shin-Etsu Chemical Co., Ltd.) as the first etch inhibitor, 0.50 wt % of tetraethoxysilane (manufactured by Fujifilm Wako Pure Chemical Corporation) as the second etch inhibitor, and 0.30 wt % of succinic acid dihydrazide (manufactured by Fujifilm Wako Pure Chemical Corporation) as the deposition inhibitor, were added and dissolved to obtain an etching solution composition of Example 29.

### Example 30

A predetermined amount of silicon nitride was dissolved in the etching solution composition of Example 29 so that the concentration of Si derived from silicon nitride in the solution was adjusted to 2500 ppm, to obtain an etching solution composition of Example 30, which thus originally contained silicon nitride.

### Example 31

To an 80% phosphoric acid prepared by a procedure similar to that of Example 29, 15.40 wt % of a hydrolysate of 3-aminopropyltriethoxysilane (manufactured by Shin-Etsu Chemical Co., Ltd.) as the first etch inhibitor, 0.40 wt % of tetraethoxysilane (manufactured by Fujifilm Wako Pure Chemical Corporation) as the second etch inhibitor, and 0.30 wt % of adipic acid dihydrazide (manufactured by Fujifilm Wako Pure Chemical Corporation) as the deposition inhibitor, were added and dissolved to obtain an etching solution composition of Example 31.

### Example 32

A predetermined amount of silicon nitride was dissolved in the etching solution composition of Example 31 so that the concentration of Si derived from silicon nitride in the solution was adjusted to 3000 ppm, to obtain an etching solution composition of Example 32, which thus originally contained silicon nitride.

### Example 33

To an 87% phosphoric acid prepared by a procedure similar to that of Example 1, 2.40 wt % of a hydrolysate of 3-aminopropyltrimethoxysilane (manufactured by Shin-Etsu Chemical Co., Ltd.) as the first etch inhibitor, 0.30 wt % of the siloxane compound represented by chemical structural formula (2) as the second etch inhibitor, and 0.40 wt % of adipic acid dihydrazide (manufactured by Fujifilm Wako Pure Chemical Corporation) as the deposition inhibitor, were added and dissolved to obtain an etching solution composition of Example 33.

### Example 34

A predetermined amount of silicon nitride was dissolved in the etching solution composition of Example 33 so that the concentration of Si derived from silicon nitride in the solution was adjusted to 400 ppm, to obtain an etching solution composition of Example 34, which thus originally contained silicon nitride.

### Comparative Example 1

To an 87% phosphoric acid prepared by a procedure similar to that of Example 1, 4.00 wt % of 3-aminopropyltrimethoxysilane (manufactured by Shin-Etsu Chemical Co., Ltd.) as the first etch inhibitor, and 0.30 wt % of succinic acid dihydrazide (manufactured by Fujifilm Wako Pure Chemical Corporation) as the deposition inhibitor, were added and dissolved to obtain an etching solution composition of Comparative Example 1.

### Comparative Example 2

To an 87% phosphoric acid prepared by a procedure similar to that of Example 1, 4.00 wt % of 3-aminopropyltriethoxysilane (manufactured by Shin-Etsu Chemical Co., Ltd.) as the first etch inhibitor, and 0.30 wt % of acetohydrazide chloride (manufactured by Fujifilm Wako Pure Chemical Corporation) as the deposition inhibitor, were added and dissolved to obtain an etching solution composition of Comparative Example 2.

### Comparative Example 3

To an 87% phosphoric acid prepared by a procedure similar to that of Example 1, 4.00 wt % of 3-aminopropyltriethoxysilane (manufactured by Shin-Etsu Chemical Co., Ltd.) as the first etch inhibitor, and 0.30 wt % of succinic acid 2,2-dimethylhydrazide (manufactured by Fujifilm Wako Pure Chemical Corporation) as the deposition inhibitor, were added and dissolved to obtain an etching solution composition of Comparative Example 3.

### Comparative Example 4

To an 87% phosphoric acid prepared by a procedure similar to that of Example 1, 1.00 wt % of 3-aminopropyltrimethoxysilane (manufactured by Shin-Etsu Chemical Co., Ltd.) and 1.00% of 3-aminopropyltriethoxysilane (manufactured by Shin-Etsu Chemical Co., Ltd.) as the first etch inhibitor, and 0.10 wt % of adipic acid dihydrazide (manufactured by Fujifilm Wako Pure Chemical Corporation) as the deposition inhibitor, were added and dissolved to obtain an etching solution composition of Comparative Example 4.

### Comparative Example 5

To an 87% phosphoric acid prepared by a procedure similar to that of Example 1, 3.00 wt % of N-2-(aminoethyl)-3-aminopropyltrimethoxysilane (manufactured by Shin-Etsu Chemical Co., Ltd.) as the first etch inhibitor, and 0.30 wt % of adipic acid dihydrazide (manufactured by Fujifilm Wako Pure Chemical Corporation) as the deposition inhibitor, were added and dissolved to obtain an etching solution composition of Comparative Example 5.

### Comparative Example 6

To an 87% phosphoric acid prepared by a procedure similar to that of Example 1, 6.00 wt % of N-2-(aminoethyl)-3-aminopropylmethyldimethoxysilane (manufactured by Shin-Etsu Chemical Co., Ltd.) as the first etch inhibitor, and 0.30 wt % of acetohydrazide chloride (manufactured by Fujifilm Wako Pure Chemical Corporation) as the deposition inhibitor, were added and dissolved to obtain an etching solution composition of Comparative Example 6.

### Comparative Example 7

To an 87% phosphoric acid prepared by a procedure similar to that of Example 1, 0.20 wt % of 1,3-dimethyltetramethoxydisiloxane (manufactured by Fluorochem Ltd.), having chemical structural formula (1), as the second etch inhibitor, and 0.10 wt % of adipic acid dihydrazide (manufactured by Fujifilm Wako Pure Chemical Corporation) as the deposition inhibitor, were added and dissolved. Thereafter, a predetermined amount of silicon nitride was dissolved in the resultant solution so that the concentration of Si derived from silicon nitride in the solution was adjusted to 50 ppm, to obtain an etching solution composition of Comparative Example 7, which thus originally contained silicon nitride.

### Comparative Example 8

To an 87% phosphoric acid prepared by a procedure similar to that of Example 1, 0.15 wt % of the siloxane compound represented by chemical structural formula (2) as the second etch inhibitor, and 0.10 wt % of adipic acid dihydrazide (manufactured by Fujifilm Wako Pure Chemical Corporation) as the deposition inhibitor, were added and dissolved. A predetermined amount of silicon nitride was dissolved in the resultant solution so that the concentration of Si derived from silicon nitride in the solution was adjusted to 50 ppm, to obtain an etching solution composition of Comparative Example 8, which thus originally contained silicon nitride.

### Comparative Example 9

To an 87% phosphoric acid prepared by a procedure similar to that of Example 1, 0.30 wt % of the siloxane compound represented by chemical structural formula (2) as the second etch inhibitor, and 0.10 wt % of adipic acid dihydrazide (manufactured by Fujifilm Wako Pure Chemical Corporation) as the deposition inhibitor, were added and dissolved to obtain an etching solution composition of Comparative Example 9.

### Comparative Example 10

To an 87% phosphoric acid prepared by a procedure similar to that of Example 1, 0.20 wt % of tetramethoxysilane (manufactured by Fujifilm Wako Pure Chemical Corporation) as the second etch inhibitor, and 0.10 wt % of azelaic acid dihydrazide (manufactured by Fujifilm Wako Pure Chemical Corporation) as the deposition inhibitor, were added and dissolved to obtain an etching solution composition of Comparative Example 10.

### Comparative Example 11

To an 87% phosphoric acid prepared by a procedure similar to that of Example 1, 0.30 wt % of tetramethoxysilane (manufactured by Fujifilm Wako Pure Chemical Corporation) as the second etch inhibitor, and 0.10 wt % of adipic acid dihydrazide (manufactured by Fujifilm Wako Pure Chemical Corporation) as the deposition inhibitor, were added and dissolved. A predetermined amount of silicon nitride was dissolved in the resultant solution so that the concentration of Si derived from silicon nitride in the solution was adjusted to 50 ppm, to obtain an etching solution composition of Comparative Example 11, which thus originally contained silicon nitride.

### Comparative Example 12

To an 87% phosphoric acid prepared by a procedure similar to that of Example 1, 0.50 wt % of tetrabutoxysilane (manufactured by Fujifilm Wako Pure Chemical Corporation) as the second etch inhibitor, and 0.10 wt % of adipic acid dihydrazide (manufactured by Fujifilm Wako Pure Chemical Corporation) as the deposition inhibitor, were added and dissolved to obtain an etching solution composition of Comparative Example 12.

### Comparative Example 13

To an 87% phosphoric acid prepared by a procedure similar to that of Example 1, 1.00 wt % of hexamethyldisiloxane (manufactured by Fujifilm Wako Pure Chemical Corporation), and 0.10 wt % of adipic acid dihydrazide (manufactured by Fujifilm Wako Pure Chemical Corporation) as the deposition inhibitor, were added and dissolved to obtain an etching solution composition of Comparative Example 13. It should be noted that hexamethyldisiloxane does not have, in the molecular structure, at least four of alkoxy groups and/or hydroxy groups, and therefore, does not serve as the second etch inhibitor, but is shown in the second etch inhibitor column of Table 2 for comparison.

### Comparative Example 14

To an 80% phosphoric acid prepared by a procedure similar to that of Example 29, 15.70 wt % of 3-aminopropyltrimethoxysilane (manufactured by Shin-Etsu Chemical Co., Ltd.) as the first etch inhibitor, and 0.30 wt % of succinic acid dihydrazide (manufactured by Fujifilm Wako Pure Chemical Corporation) as the deposition inhibitor, were added and dissolved to obtain an etching solution composition of Comparative Example 14.

### Comparative Example 15

To an 80% phosphoric acid prepared by a procedure similar to that of Example 29, 15.40 wt % of 3-aminopropyltriethoxysilane (manufactured by Shin-Etsu Chemical Co., Ltd.) as the first etch inhibitor, and 0.30 wt % of adipic acid dihydrazide (manufactured by Fujifilm Wako Pure Chemical Corporation) as the deposition inhibitor, were added and dissolved to obtain an etching solution composition of Comparative Example 15.

### Comparative Example 16

To an 87% phosphoric acid prepared by a procedure similar to that of Example 1, 2.40 wt % of a hydrolysate of 3-aminopropyltrimethoxysilane (manufactured by Shin-Etsu Chemical Co., Ltd.) as the first etch inhibitor, and 0.40 wt % of adipic acid dihydrazide (manufactured by Fujifilm Wako Pure Chemical Corporation) as the deposition inhibitor, were added and dissolved to obtain an etching solution composition of Comparative Example 16.

### Comparative Example 17

To an 87% phosphoric acid prepared by a procedure similar to that of Example 1, 0.30 wt % of tetrachloride silicon (manufactured by Tokyo Chemical Industry Co., Ltd.) as the second etch inhibitor, and 0.30 wt % of adipic acid dihydrazide (manufactured by Fujifilm Wako Pure Chemical Corporation) as the deposition inhibitor, were added and dissolved to obtain an etching solution composition of Comparative Example 17.

### Comparative Example 18

To an 87% phosphoric acid prepared by a procedure similar to that of Example 1, 0.05 wt % of hexachlorodisilane (manufactured by Tokyo Chemical Industry Co., Ltd.) as the second etch inhibitor, and 0.40 wt % of acetohydrazide chloride (manufactured by Fujifilm Wako Pure Chemical Corporation) as the deposition inhibitor, were added and dissolved to obtain an etching solution composition of Comparative Example 18.

### Comparative Example 19

To an 87% phosphoric acid prepared by a procedure similar to that of Example 1, 0.05 wt % of hexamethoxydisiloxane (manufactured by Tokyo Chemical Industry Co., Ltd.), represented by chemical structural formula (4), as the second etch inhibitor, and 0.40 wt % of adipic acid dihydrazide (manufactured by Fujifilm Wako Pure Chemical Corporation) as the deposition inhibitor, were added and dissolved to obtain an etching solution composition of Comparative Example 19.

### Reference Example 1

An 87% phosphoric acid prepared by a procedure similar to that of Example 1 was directly used as an etching solution of Reference Example 1.

### <Etch Test 1>

Next, test conditions, measuring methods, and the like in an etch test that was conducted using the etching solution compositions of Examples 1 to 34 and Comparative Examples 1 to 19 and the etching solution of Reference Example 1 will be described.

### [Test Conditions]

Testpieces of silicon nitride (silicon nitride films) and testpieces of silicon oxide (silicon oxide films), which were to be subjected to etching, were prepared. Each testpiece had a square shape with a size of 1.5 cm×1.5 cm. The etching process time (t) was 20 minutes for the silicon nitride film and 60 minutes for the silicon oxide film. The etching process temperature was 158° C.

[Method for Measuring Concentration of Si Derived from Silicon Nitride]

The Si concentration [Si 1a] of an etching solution composition, and the Si concentration [Si 1b] of the etching solution composition after the solution was consumed, so that silicon nitride was dissolved in the solution, were measured. The concentration [Si 1] of Si derived from silicon nitride was calculated by:

$$[ Si 1 ] = [ Si 1 b ] - [ Si 1 a ] \qquad ( 1 )$$

Incidentally, the Si concentration [Si 1a] of an etching solution composition is derived from the etch inhibitor contained in the etching solution composition. It should be noted that the Si concentration of a solution was measured by ICP atomic emission spectrometry (ICP-AES) using a sequential high resolution ICP optical emission spectrometer (product name: “PS3520,” manufactured by Hitachi High-Tech Science Corporation).

### [Method for Measuring Etch Rate]

The thickness [T₁ₐ] of a silicon nitride film before an etching process and the thickness [T_{1b}] of the silicon nitride film after the etching process were measured. The etch rate [R₁] was calculated by:

$$[ {R}_{1} ] = ( [ {T}_{1 a} ] - [ {T}_{1 b} ] ) / t ( 20 minutes ) \qquad ( 2 )$$

Likewise, the thickness [T₂ₐ] of a silicon oxide film before an etching process and the thickness [T_{2b}] of the silicon oxide film after the etching process were measured. The etch rate [R₂] of silicon oxide was calculated by:

$$[ {R}_{2} ] = ( [ {T}_{2 a} ] - [ {T}_{2 b} ] ) / t ( 60 minutes ) \qquad ( 3 )$$

The ratio of the silicon nitride etch rate [R₁] to the silicon oxide etch rate [R₂] is referred to as a selectivity ratio [R₁/R₂], which is an indicator for the etch selectivity of silicon nitride. It should be noted that the thickness was measured using a light interference thickness monitor (product name: “Ava Thinfilm,” manufactured by Avantes, resolution: 1 nm).

### [Silica Deposition Assessment of Surface of Silicon Oxide Film]

The difference ([T₂ₐ]−[T_{2b}]) between the thickness [T₂ₐ] of a silicon oxide film before an etching process and the thickness [T_{2b}] of the silicon oxide film after the etching process is calculated. If the thickness after the etching process increases (the difference has a negative value), it can be determined that silica is deposited on the surface of silicon oxide.

The specifications of the etching solution compositions of Examples 1 to 34, the specifications of the etching solution compositions of Comparative Examples 1 to 19, and the specifications of the etching solution of Reference Example 1, are shown in Tables 1 to 3. It should be noted that chemical structural formula (1), chemical structural formula (2), chemical structural formula (3), and chemical structural formula (4) shown in the second etch inhibitor column are the above-described 1,3-dimethyltetramethoxydisiloxane, siloxane compound, or hexamethoxydisiloxane. The results of the etch test conducted using the etching solution compositions and the etching solution are additionally shown on Tables 1 to 3.

TABLE 1

| | Etching solution | | |
|---|---|---|---|
| | composition (wt %) | | |
| | Inorganic acid | First etch inhibitor | Second etch inhibitor |
| Example 1 | Phospharic acid 87 | 3-aminopropyltrimethoxysilane 3.00 | Chemical structural formula (1) 0.20 |
| Example 2 | Phospharic acid 87 | 3-aminopropyltrimethoxysilane 3.00 | Chemical structural formula (1) 0.20 |
| Example 3 | Phospharic acid 87 | 3-aminopropyltrimethoxysilane 3.00 | Chemical structural formula (2) 0.09 |
| Example 4 | Phospharic acid 87 | 3-aminopropyltrimethoxysilane 3.00 | Chemical structural formula (2) 0.09 |
| Example 5 | Phospharic acid 87 | 3-aminopropyltrimethoxysilane 4.00 | Chemical structural formula (3) 0.60 |
| Example 6 | Phospharic acid 87 | 3-aminopropyltrimethoxysilane 4.00 | Chemical structural formula (3) 0.60 |
| Example 7 | Phospharic acid 87 | 3-aminopropyltriethoxysilane 4.00 | Chemical structural formula (1) 0.20 |
| Example 8 | Phospharic acid 87 | 3-aminopropyltriethoxysilane 4.00 | Chemical structural formula (1) 0.20 |
| Example 9 | Phospharic acid 87 | 3-aminopropyltriethoxysilane 4.00 | Chemical structural formula (2) 0.09 |
| Example 10 | Phospharic acid 87 | 3-aminopropyltriethoxysilane 4.00 | Chemical structural formula (2) 0.09 |
| Example 11 | Phospharic acid 87 | 3-aminopropyltriethoxysilane 4.00 | Chemical structural formula (2) 0.09 |
| Example 12 | Phospharic acid 87 | 3-aminopropyltriethoxysilane 4.00 | Chemical structural formula (2) 0.09 |
| Example 13 | Phospharic acid 87 | N-2-(aminoethyl)-3- | Chemical structural formula (2) 0.12 |
| | | aminopropyltrimethoxysilane 3.00 | |
| Example 14 | Phospharic acid 87 | N-2-(aminoethyl)-3- | Chemical structural formula (2) 0.12 |
| | | aminopropyltrimethoxysilane 3.00 | |
| Example 15 | Phospharic acid 87 | N-2-(aminoethyl)-3- | Chemical structural formula (2) 0.09 |
| | | aminopropylmethyldimethoxysilane 6.00 | |
| Example 16 | Phospharic acid 87 | N-2-(aminoethyl)-3- | Chemical structural formula (2) 0.09 |
| | | aminopropylmethyldimethoxysilane 6.00 | |
| Example 17 | Phospharic acid 87 | 3-aminopropyltrimethoxysilane 4.00 | Tetramethoxysilane 0.04 |
| Example 18 | Phospharic acid 87 | 3-aminopropyltrimethoxysilane 4.00 | Tetramethoxysilane 0.04 |
| Example 19 | Phospharic acid 87 | 3-aminopropyltriethoxysilane 4.00 | Tetraethoxysilane 0.20 |
| Example 20 | Phospharic acid 87 | 3-aminopropyltriethoxysilane 4.00 | Tetraethoxysilane 0.20 |
| Example 21 | Phospharic acid 87 | N-2-(aminoethyl)-3- | Tetrabutoxysilane 0.30 |
| | | aminopropyltrimethoxysilane 4.00 | |
| Example 22 | Phospharic acid 87 | N-2-(aminoethyl)-3- | Tetrabutoxysilane 0.30 |
| | | aminopropyltrimethoxysilane 4.00 | |

| | | | | | | SiO |
|---|---|---|---|---|---|---|
| | | Concentration | SiN | SiO | | film |
| | Etching solution | of SiN- | etch | etch | Selectivity | thickness |
| | composition (wt %) | derived Si | rate [R1] | rate [R2] | ratio | difference |
| | Deposition inhibitor | (ppm) | (nm/min) | (nm/min) | [R1/R2] | (nm) |
| Example 1 | Adipic acid dihydrazide 0.30 | 0 | 2.97 | 0.008 | 371 | 0.5 |
| Example 2 | Adipic acid dihydrazide 0.30 | 200 | 3.48 | 0.000 | ∞ | 0 |
| Example 3 | Adipic acid dihydrazide 0.30 | 0 | 3.17 | 0.000 | ∞ | 0 |
| Example 4 | Adipic acid dihydrazide 0.30 | 200 | 3.33 | 0.000 | ∞ | 0 |
| Example 5 | Succinic acid dihydrazide 0.30 | 0 | 3.23 | 0.012 | 269 | 0.7 |
| Example 6 | Succinic acid dihydrazide 0.30 | 200 | 2.74 | 0.000 | ∞ | 0 |
| Example 7 | Succinic acid dihydrazide 0.30 | 0 | 3.56 | 0.008 | 445 | 0.5 |
| Example 8 | Succinic acid dihydrazide 0.30 | 200 | 3.11 | 0.000 | ∞ | 0 |
| Example 9 | Acetohydrazide chloride 0.30 | 0 | 3.24 | 0.012 | 270 | 0.7 |
| Example 10 | Acetohydrazide chloride 0.30 | 200 | 3.13 | 0.000 | ∞ | 0 |
| Example 11 | Succinic acid 2,2- | 0 | 3.40 | 0.007 | 486 | 0.4 |
| | dimethylhydrazide 0.30 | | | | | |
| Example 12 | Succinic acid 2,2- | 200 | 3.29 | 0.000 | ∞ | 0 |
| | dimethylhydrazide 0.30 | | | | | |
| Example 13 | Adipic acid dihydrazide 0.30 | 0 | 3.51 | 0.007 | 501 | 0.4 |
| Example 14 | Adipic acid dihydrazide 0.30 | 200 | 2.89 | 0.000 | ∞ | 0 |
| Example 15 | Acetohydrazide chloride 0.30 | 0 | 3.58 | 0.025 | 143 | 1.5 |
| Example 16 | Acetohydrazide chloride 0.30 | 200 | 3.18 | 0.000 | ∞ | 0 |
| Example 17 | Azelaic acid dihydrazide 0.30 | 0 | 2.84 | 0.008 | 355 | 0.5 |
| Example 18 | Azelaic acid dihydrazide 0.30 | 200 | 2.89 | 0.000 | ∞ | 0 |
| Example 19 | Adipic acid dihydrazide 0.40 | 0 | 3.17 | 0.010 | 317 | 0.6 |
| Example 20 | Adipic acid dihydrazide 0.40 | 200 | 2.85 | 0.000 | ∞ | 0 |
| Example 21 | Adipic acid dihydrazide 0.40 | 0 | 3.02 | 0.010 | 302 | 0.6 |
| Example 22 | Adipic acid dihydrazide 0.40 | 200 | 3.44 | 0.000 | ∞ | 0 |

TABLE 2

| | Etching solution | | |
|---|---|---|---|
| | composition (wt %) | | |
| | Inorganic acid | First etch inhibitor | Second etch inhibitor |
| Example 23 | Phospharic acid 87 | 3-aminopropyltrimethoxysilane 4.00 | Tetrachloride silicon 0.10 |
| Example 24 | Phospharic acid 87 | 3-aminopropyltrimethoxysilane 4.00 | Tetrachloride silicon 0.10 |
| Example 25 | Phospharic acid 87 | 3-aminopropyltriethoxysilane 4.00 | Hexachlorodisilane 0.05 |
| Example 26 | Phospharic acid 87 | 3-aminopropyltriethoxysilane 4.00 | Hexachlorodisilane 0.05 |
| Example 27 | Phospharic acid 87 | 3-aminopropyltrimethoxysilane 4.00 | Chemical structural formula (4) 0.05 |
| Example 28 | Phospharic acid 87 | 3-aminopropyltrimethoxysilane 4.00 | Chemical structural formula (4) 0.05 |
| Example 29 | Phospharic acid 80 | 3-aminopropyltrimethoxysilane 15.70 | Tetraethoxysilane 0.50 |
| Example 30 | Phospharic acid 80 | 3-aminopropyltrimethoxysilane 15.70 | Tetraethoxysilane 0.50 |
| Example 31 | Phospharic acid 80 | Hydrolysate of 3- | Tetraethoxysilane 0.40 |
| | | aminopropyltriethoxysilane 15.40 | |
| Example 32 | Phospharic acid 80 | Hydrolysate of 3- | Tetraethoxysilane 0.40 |
| | | aminopropyltriethoxysilane 15.40 | |
| Example 33 | Phospharic acid 87 | Hydrolysate of 3- | Chemical structural formula (2) 0.30 |
| | | aminopropyltrimethoxysilane 2.40 | |
| Example 34 | Phospharic acid 87 | Hydrolysate of 3- | Chemical structural formula (2) 0.30 |
| | | aminopropyltrimethoxysilane 2.40 | |

| | | | | | | SiO |
|---|---|---|---|---|---|---|
| | | Concentration | SiN | SiO | | film |
| | Etching solution | of SiN- | etch | etch | Selectivity | thickness |
| | composition (wt %) | derived Si | rate [R1] | rate [R2] | ratio | difference |
| | Deposition inhibitor | (ppm) | (nm/min) | (nm/min) | [R1/R2] | (nm) |
| Example 23 | Adipic acid dihydrazide 0.30 | 0 | 3.17 | 0.012 | 264 | 0.7 |
| Example 24 | Adipic acid dihydrazide 0.30 | 200 | 3.08 | 0.000 | ∞ | 0 |
| Example 25 | Acetohydrazide chloride 0.40 | 0 | 3.25 | 0.015 | 217 | 0.9 |
| Example 26 | Acetohydrazide chloride 0.40 | 200 | 3.36 | 0.000 | ∞ | 0 |
| Example 27 | Adipic acid dihydrazide 0.40 | 0 | 2.98 | 0.008 | 373 | 0.5 |
| Example 28 | Adipic acid dihydrazide 0.40 | 200 | 3.14 | 0.000 | ∞ | 0 |
| Example 29 | Succinic acid dihydrazide 0.30 | 0 | 2.94 | 0.000 | ∞ | 0 |
| Example 30 | Succinic acid dihydrazide 0.30 | 2500 | 2.13 | 0.000 | ∞ | 0 |
| Example 31 | Adipic acid dihydrazide 0.30 | 0 | 2.14 | 0.000 | ∞ | 0 |
| Example 32 | Adipic acid dihydrazide 0.30 | 3000 | 1.85 | 0.000 | ∞ | 0 |
| Example 33 | Adipic acid dihydrazide 0.40 | 0 | 2.62 | 0.000 | ∞ | 0 |
| Example 34 | Adipic acid dihydrazide 0.40 | 400 | 2.43 | 0.000 | ∞ | 0 |

TABLE 3

| | Etching solution | | |
|---|---|---|---|
| | composition (wt %) | | |
| | Inorganic acid | First etch inhibitor | Second etch inhibitor |
| Comparative Example 1 | Phospharic acid 87 | 3-aminopropyltrimethoxysilane 4.00 | — |
| Comparative Example 2 | Phospharic acid 87 | 3-aminopropyltriethoxysilane 4.00 | — |
| Comparative Example 3 | Phospharic acid 87 | 3-aminopropyltriethoxysilane 4.00 | — |
| Comparative Example 4 | Phospharic acid 87 | 3-aminopropyltrimethoxysilane 1.00 | — |
| | | 3-aminopropyltriethoxysilane 1.00 | |
| Comparative Example 5 | Phospharic acid 87 | N-2-(aminoethyl)-3- | — |
| | | aminopropyltrimethoxysilane 3.00 | |
| Comparative Example 6 | Phospharic acid 87 | N-2-(aminoethyl)-3- | — |
| | | aminopropylmethyldimethoxysilane 6.00 | |
| Comparative Example 7 | Phospharic acid 87 | — | Chemical structural formula (1) 0.20 |
| Comparative Example 8 | Phospharic acid 87 | — | Chemical structural formula (2) 0.15 |
| Comparative Example 9 | Phospharic acid 87 | — | Chemical structural formula (2) 0.30 |
| Comparative Example 10 | Phospharic acid 87 | — | Tetramethoxysilane 0.20 |
| Comparative Example 11 | Phospharic acid 87 | — | Tetramethoxysilane 0.30 |
| Comparative Example 12 | Phospharic acid 87 | — | Tetrabutoxysilane 0.50 |
| Comparative Example 13 | Phospharic acid 87 | — | Hexamethyldisiloxane 1.00 |
| Comparative Example 14 | Phospharic acid 80 | 3-aminopropyltrimethoxysilane 15.70 | — |
| Comparative Example 15 | Phospharic acid 80 | Hydrolysate of 3- | — |
| | | aminopropyltriethoxysilane 15.40 | |
| Comparative Example 16 | Phospharic acid 87 | Hydrolysate of 3- | — |
| | | aminopropyltrimethoxysilane 2.40 | |
| Comparative Example 17 | Phospharic acid 87 | — | Tetrachloride silicon 0.30 |
| Comparative Example 18 | Phospharic acid 87 | — | Hexachlorodisilane 0.05 |
| Comparative Example 19 | Phospharic acid 87 | — | Chemical structural formula (4) 0.05 |
| Reference Example 1 | Phospharic acid 87 | — | — |

| | | | | | | SiO |
|---|---|---|---|---|---|---|
| | | Concentration | SiN | SiO | | film |
| | Etching solution | SiN- | etch | etch | Selectivity | thickness |
| | composition (wt %) | derived Si | rate [R₁] | rate [R₂] | ratio | difference |
| | Deposition inhibitor | (ppm) | (nm/min) | (nm/min) | [R₁/R₂] | (nm) |
| Comparative Example 1 | Succinic acid dihydrazide 0.30 | 0 | 3.28 | 0.032 | 103 | 1.3 |
| Comparative Example 2 | Acetohydrazide chloride 0.30 | 0 | 3.18 | 0.025 | 127 | 1.5 |
| Comparative Example 3 | Succinic acid 2,2- | 0 | 3.59 | 0.037 | 97 | 1.3 |
| | dimethylhydrazide 0.30 | | | | | |
| Comparative Example 4 | Adipic acid dihydrazide 0.10 | 0 | 3.55 | 0.035 | 101 | 2.1 |
| Comparative Example 5 | Adipic acid dihydrazide 0.30 | 0 | 3.56 | 0.033 | 108 | 2.0 |
| Comparative Example 6 | Acetohydrazide chloride 0.30 | 0 | 3.82 | 0.072 | 53 | 4.3 |
| Comparative Example 7 | Adipic acid dihydrazide 0.10 | 50 | 4.29 | −0.008 | −536 | −0.5 |
| Comparative Example 8 | Adipic acid dihydrazide 0.10 | 50 | 3.69 | −0.028 | −132 | −1.7 |
| Comparative Example 9 | Adipic acid dihydrazide 0.10 | 0 | 3.95 | −0.035 | −113 | −2.1 |
| Comparative Example 10 | Azelaic acid dihydrazide 0.10 | 0 | 3.76 | −0.010 | −376 | −0.6 |
| Comparative Example 11 | Adipic acid dihydrazide 0.10 | 50 | 4.05 | −0.010 | −405 | −0.6 |
| Comparative Example 12 | Adipic acid dihydrazide 0.10 | 0 | 3.60 | −0.020 | −180 | −1.2 |
| Comparative Example 13 | Adipic acid dihydrazide 0.10 | 0 | 4.40 | 0.177 | 25 | 10.6 |
| Comparative Example 14 | Succinic acid dihydrazide 0.30 | 0 | 3.00 | 0.023 | 130 | 1.4 |
| Comparative Example 15 | Adipic acid dihydrazide 0.30 | 0 | 2.37 | 0.020 | 119 | 1.2 |
| Comparative Example 16 | Adipic acid dihydrazide 0.40 | 0 | 2.86 | 0.022 | 130 | 1.3 |
| Comparative Example 17 | Adipic acid dihydrazide 0.30 | 0 | 4.13 | −0.020 | −207 | −1.2 |
| Comparative Example 18 | Acetohydrazide chloride 0.40 | 0 | 3.62 | −0.008 | −453 | −0.5 |
| Comparative Example 19 | Adipic acid dihydrazide 0.40 | 0 | 3.94 | −0.008 | −493 | −0.5 |
| Reference Example 1 | — | 0 | 5.90 | 0.22 | 27 | 6.6 |

### Discussion

As a result of the etch test, the following new findings were obtained on the etching solution composition of the present invention.

[1] The etching solution compositions of Examples 1 to 34, which are based on phosphoric acid (inorganic acid) and contain: 3-aminopropyltrimethoxysilane or a hydrolysate thereof, 3-aminopropyltriethoxysilane or a hydrolysate thereof, N-2-(aminoethyl)-3-aminopropyltrimethoxysilane, or N-2-(aminoethyl)-3-aminopropylmethyldimethoxysilane (first etch inhibitor having, in the molecular structure, at most three of alkoxy groups, hydroxy groups, and/or functional groups that are a precursor of a hydroxy group); 1,3-dimethyltetramethoxydisiloxane, the siloxane compound represented by chemical structural formula (2), the siloxane compound represented by chemical structural formula (3), tetramethoxysilane, tetraethoxysilane, tetrabutoxysilane, tetrachloride silicon, hexachlorodisilane, or hexamethoxydisiloxane (second etch inhibitor having, in the molecular structure, at least four of alkoxy groups, hydroxy groups, and/or functional groups that are a precursor of a hydroxy group); and a hydrazide such as adipic acid dihydrazide, succinic acid dihydrazide, acetohydrazide chloride, succinic acid 2,2-dimethylhydrazide, or azelaic acid dihydrazide (deposition inhibitor), can have a reduced silicon oxide etch rate [R₂], resulting in an increased etch selectivity of silicon nitride film, and therefore, a higher selectivity ratio [R₁/R₂]. In the case in which Si derived from silicon nitride was not contained in the solution for comparison, the selectivity ratio [R₁/R₂] of the etching solution composition of Example 15, which had the lowest selectivity ratio ([R₁/R₂]=143), was about 5.3 times as high as the selectivity ratio ([R₁/R₂]=27) of the etching solution of Reference Example 1, which contained only phosphoric acid (inorganic acid). In addition, in the case of the etching solution composition of Example 16, which was obtained by modifying the etching solution composition of Example 15 such that the concentration of Si derived from silicon nitride in the solution was changed to 200 ppm, the value of the selectivity ratio [R₁/R₂] was ∞ (infinite), and the deposition of silica on the surface of silicon oxide was reliably reduced. This tendency was similarly observed in the examples that were not related to Examples 15 and 16.

[2] The etching solution compositions of Comparative Examples 1 to 6 and 14 to 16, which are based on phosphoric acid (inorganic acid) and contain: 3-aminopropyltrimethoxysilane or a hydrolysate thereof, 3-aminopropyltriethoxysilane or a hydrolysate thereof, N-2-(aminoethyl)-3-aminopropyltrimethoxysilane, or N-2-(aminoethyl)-3-aminopropylmethyldimethoxysilane (first etch inhibitor having, in the molecular structure, at most three of alkoxy groups, hydroxy groups, and/or functional groups that are a precursor of a hydroxy group), and adipic acid dihydrazide, succinic acid dihydrazide, acetohydrazide chloride, or succinic acid 2,2-dimethylhydrazide (deposition inhibitor), and does not contain a second etch inhibitor having, in the molecular structure, at least four of alkoxy groups, hydroxy groups, and/or functional groups that are a precursor of a hydroxy group, had a high etch rate [R₂] of silicon oxide, and therefore, did not have improved etch selectivity of silicon nitride film, and had a selectivity ratio [R₁/R₂] of at most 130.

[3] The etching solution compositions of Comparative Examples 7 to 12 and 17 to 19, which are based on phosphoric acid (inorganic acid) and contain: 1,3-dimethyltetramethoxydisiloxane, the siloxane compound represented by chemical structural formula (2), tetramethoxysilane, tetrabutoxysilane, tetrachloride silicon, hexachlorodisilane, or hexamethoxydisiloxane (second etch inhibitor having, in the molecular structure, at least four of alkoxy groups, hydroxy groups, and/or functional groups that are a precursor of a hydroxy group), and adipic acid dihydrazide, or acetohydrazide chloride (deposition inhibitor), and does not contain a first etch inhibitor having, in the molecular structure, at most three of alkoxy groups, hydroxy groups, and/or functional groups that are a precursor of a hydroxy group, had a negative etch rate [R₂] of silicon oxide. In these comparative examples, the deposition of silica on the surface of silicon oxide was observed. It should be noted that the etching solution composition of Comparative Example 13, which is based on phosphoric acid (inorganic acid) and contains hexamethyldisiloxane and adipic acid dihydrazide (deposition inhibitor), had only a selectivity ratio ([R₁/R₂]=25) similar to that of the etching solution of Reference Example 1, which contains only phosphoric acid (inorganic acid).

[4] Thus, it has been clarified that the etching solution compositions of Examples 1 to 34 (the present invention), which simultaneously contain a first etch inhibitor having, in the molecular structure, at most three of alkoxy groups, hydroxy groups, and/or functional groups that are a precursor of a hydroxy group, a second etch inhibitor having, in the molecular structure, at least four of alkoxy groups, hydroxy groups, and/or functional groups that are a precursor of a hydroxy group, a deposition inhibitor containing a hydrazide, are capable of both having a high etch selectivity of silicon nitride, and reducing the deposition of silica on the surface of silicon oxide. In addition, according to Examples 30 and 32, the etching solution composition of the present invention can be used repeatedly even when the concentration of Si derived from silicon nitride in the solution is 2500 to 3000 ppm. It was found that even when the concentration of Si derived from silicon nitride in the solution has reached to some degree, the selectivity ratio [R₁/R₂] can be significantly improved while the deposition of silica on the surface of silicon oxide is reduced. It should be noted that although no example is shown, the etching solution composition of the present invention can be used repeatedly even when the concentration of Si derived from silicon nitride in the solution is a considerably high concentration (about 3000 ppm), even in the case where the etching solution composition is different from those of Examples 30 and 32.

### INDUSTRIAL APPLICABILITY

The etching solution composition of the present invention is particularly useful for industrial manufacture of NAND type flash memory having a three-dimensional structure (3D NAND), and is also applicable to industrial manufacture of conventional memory having a two-dimensional structure.

What is claimed is:

1. An inorganic acid-based etching solution composition for selectively etching away silicon nitride from a semiconductor containing silicon nitride and silicon oxide, the etching solution composition comprising:
an etch inhibitor that reduces etching of silicon oxide; and
a deposition inhibitor that reduces deposition of silica on a surface of silicon oxide, wherein
the etch inhibitor includes a first etch inhibitor having, in the molecular structure, at most three of alkoxy groups, hydroxy groups, and/or functional groups that are a precursor of a hydroxy group, and a second etch inhibitor having, in the molecular structure, at least four of alkoxy groups, hydroxy groups, and/or functional groups that are a precursor of a hydroxy group.

2. The etching solution composition according to claim 1, wherein
the first etch inhibitor is a silane compound having an amino group.

3. The etching solution composition according to claim 1, wherein
the first etch inhibitor contains at least one selected from the group consisting of 3-aminopropyltrimethoxysilane, 3-aminopropyltriethoxysilane, N-2-(aminoethyl)-3-aminopropyltrimethoxysilane, and N-2-(aminoethyl)-3-aminopropylmethyldimethoxysilane, and hydrolysates of the alkoxysilanes.

4. The etching solution composition according to claim 1, wherein
the second etch inhibitor is a silane compound having at least one functional group selected from the group consisting of an alkyl group, an amino group, and a halogen group.

5. The etching solution composition according to claim 1, wherein
the second etch inhibitor contains at least one selected from the group consisting of 1,3-dimethyltetramethoxydisiloxane, represented by chemical structural formula (1): 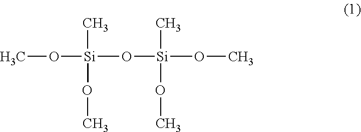
a siloxane compound represented by chemical structural formula (2): 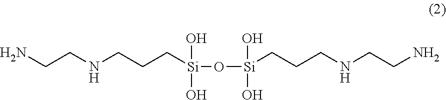 [SMILES: NCCNCCC[Si](O)(O)O[Si](O)(O)CCCNCCN]
a siloxane compound represented by chemical structural formula (3): 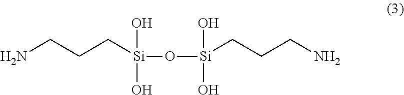 [SMILES: NCCC[Si](O)(O)O[Si](O)(O)CCCN]
hexamethoxydisiloxane, represented by chemical structural formula (4): 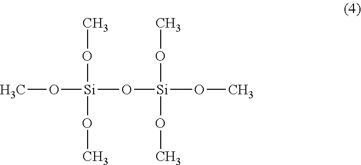
tetramethoxysilane, tetraethoxysilane, tetrabutoxysilane, tetrachloride silicon, and hexachlorodisilane.

6. The etching solution composition according to claim 1, wherein
the deposition inhibitor contains a hydrazide.

7. The etching solution composition according to claim 6, wherein
the hydrazide includes at least one selected from the group consisting of adipic acid dihydrazide, succinic acid dihydrazide, acetohydrazide chloride, succinic acid 2,2-dimethylhydrazide, and azelaic acid dihydrazide.

8. The etching solution composition according to claim 1, wherein
the etching solution composition is free from Si derived from silicon nitride in the solution when the etching solution composition is unused.

9. The etching solution composition according to claim 8, wherein
the etching solution composition is allowed to be used repeatedly until the concentration of Si derived from silicon nitride in the solution reaches 3000 ppm.

10. The etching solution composition according to claim 1, wherein
a selectivity ratio [R₁/R₂] of a silicon nitride etch rate [R₁] to a silicon oxide etch rate [R₂] is at least 5.3 times as high as that of an etching solution containing only the inorganic acid.
